(19) United States
(12) Patent Application Publication
(10) Pub. No.: US 2005/0118816 A1
(43) Pub. Date: Jun. 2, 2005

(54) Method for fabricating a semiconductor component

(76) Inventors: Franz Hirler, Isen (DE); Markus Zundel, Taufkirchen (DE)

Correspondence Address: DICKE, BILLIG & CZAJA, P.L.L.C., FIFTH STREET TOWERS, 100 SOUTH FIFTH STREET, SUITE 2250, MINNEAPOLIS, MN, 55402, US

(21) Appl. No.: 10/955,392

(22) Filed: Sep. 30, 2004

(30) Foreign Application Priority Data
Sep. 30, 2003 (DE) 103 45 447.0

(51) Int. Cl. H01L 31/062; H01L 31/113; H01L 21/302; H01L 21/461

(52) U.S. Cl. 438/689

(57) ABSTRACT

A method for fabricating a semiconductor power component is disclosed. In one embodiment, the method for fabricating a semiconductor power component includes formation of a semiconductor structure in/on a substrate, a semiconductor region serving as a stop layer being formed at the level of a target thickness of the semiconductor power component through the semiconductor structure in the semiconductor structure or in the substrate, the doping concentration of said semiconductor region being increased/reduced with respect to that of the substrate, and/or the doping type of said semiconductor region being inverted with respect to that of the substrate. At least one part of the substrate is thinned to the target thickness using an etchant whose etching rate is dependent on the concentration and/or the type of the doping, the etchant being chosen such that the thinning process is stopped or slowed down by the semiconductor region serving as a stop layer.

### CROSS-REFERENCE TO RELATED APPLICATIONS

This Utility Patent Application claims priority to German Patent Application No. DE 103 45 447.0, filed on Sep. 30, 2003, which is incorporated herein by reference.

### FIELD OF THE INVENTION

The invention relates to a method for fabricating a semiconductor component.

### BACKGROUND

Power semiconductor components, such as transistors or diodes, for example, have a specific on resistivity Rₒₙ·A, where Rₒₙ is the resistance that has to be overcome by the current when flowing through the power semiconductor component, and A represents the basic area of the power semiconductor component. The on resistivity should be as low as possible since this on the one hand minimizes a power loss of the power semiconductor component and on the other hand enables higher current densities through the power semiconductor component.

In order to reduce the proportion of the on resistivity made up by the substrate, the substrate is usually thinned as far as possible by means of a thinning-by-grinding process after the completion of the power semiconductor component. In the case of vertical low-voltage components (10 V to 100 V) with highly doped substrate basic material, said proportion is still 20 to 30% even in the thinned state. Since the thickness of the drift path of a vertical low-voltage component is very small (approximately 5 to 10 μm), and the thickness fluctuations of the starting substrate are typically up to 5 μm, it is practically no longer possible to thin the thickness fluctuations of the starting substrate to a homogeneous drift path thickness of 5 to 10 μm by means of a thinning-by-grinding process. Instead, the thickness fluctuations of the starting substrate are transferred to the thinned power semiconductor component. Furthermore, additional thickness fluctuations are produced on account of manufacturing tolerances. However, in the case of thin substrate layers around 5 to 10 μm, such thickness fluctuations also entail corresponding fluctuations in the on resistivity, which makes it more difficult to reliably determine operating parameters of the power semiconductor component. If appropriate, the substrate may even break during the thinning by grinding or during later process steps.

### SUMMARY

The present invention provides a method for fabricating a semiconductor power component. In one embodiment, the method includes formation of a semiconductor structure in/on a substrate. A semiconductor region serving as a stop layer is formed at the level of a target thickness of the semiconductor power component through the semiconductor structure in the semiconductor structure or in the substrate. The doping concentration of the semiconductor region are increased/reduced with respect to that of the substrate, and/or the doping type of the semiconductor region being inverted with respect to that of the substrate.

At least one part of the substrate is thinned to the target thickness using an etchant whose etching rate is dependent on the concentration and/or the type of the doping. The etchant is chosen such that the thinning process is stopped or slowed down by the semiconductor region serving as a stop layer.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A through 1D illustrate a first to fourth process step of a preferred embodiment of a fabrication method according to the invention.

### DETAILED DESCRIPTION

In the following Detailed Description, reference is made to the accompanying drawings, which form a part hereof, and in which is shown by way of illustration specific embodiments in which the invention may be practiced. In'this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention provides a method for fabricating a semiconductor power component which enables the on resistivity to be reduced as far as possible and at the same time enables thickness fluctuations of the thinned substrate to be avoided.

In one embodiment, the method according to the invention for fabricating a semiconductor power component includes formation of a semiconductor structure in/on a substrate, a semiconductor region serving as a stop layer being formed at the level of a target thickness of the semiconductor power component through the semiconductor structure/in the semiconductor structure or in the substrate, the doping concentration of said semiconductor region being increased/reduced with respect to that of the substrate, and/or the doping type of said semiconductor region being inverted with respect to that of the substrate, and thinning of at least one part of the substrate to the target thickness using an etchant whose etching rate is dependent on the concentration and/or the type of the doping, the etchant being chosen such that the thinning process is stopped or slowed down by the semiconductor region serving as a stop layer.

The fabrication method according to the invention can be applied to any desired semiconductor power components, for example transistors or diodes.

The fabrication method according to embodiments of the invention makes it possible to dispense with the thinning-by-grinding process. As an alternative, the etching method may be combined with the thinning-by-grinding process, i.e., a “coarse thinning” of the substrate may be effected by means of the thinning-by-grinding process, a “fine thinning” of the substrate being effected by means of the etching process, which can compensate for thickness fluctuations generated or transferred by the thinning-by-grinding process. In this case, the idea on which the fabrication method according to the invention is based is that semiconductor layers, that is to say also the semiconductor region/semiconductor structure serving as a stop layer, can be produced in an extremely homogeneous (i.e., without relatively large thickness fluctuations) and locally well defined manner by means of the process techniques that are available. It is thus possible to exactly delimit the local dimensions of an etching process by using the semiconductor stop layer as a locally exactly defined etching barrier, in contrast to the rather inaccurate thinning-by-grinding process.

In order to save costs, according to embodiments of the invention a drift path required for the semiconductor component is not formed by means of a deposition process on a highly doped substrate basic material, but rather in the substrate itself. For this purpose, it is expedient to use a lightly doped substrate and to dope the latter accordingly.

The term “semiconductor structure” is defined as a structure which comprises at least one semiconductor layer or at least one semiconductor zone. The term “semiconductor structure” furthermore encompasses any desired combinations of semiconductor, metal or insulator layers.

Thus, if for example the doping of the semiconductor region serving as a stop layer is the inverse of the doping of the substrate, and a corresponding etchant is chosen which only etches semiconductor material having the doping of the substrate, the etching process is ended or slowed down to a great extent by the stop layer. As already mentioned, it is also possible to dope the stop layer and the substrate identically (i.e., not inversely with respect to one another) and to use different doping concentrations instead. The etching process is then locally delimited by the choice of an etchant that is dependent on the doping concentration if the doping concentration difference is high enough.

The thinning process of the substrate may be affected, for example, by etching away the substrate in whole-area fashion.

As an alternative, the thinning process of the substrate preferably comprises the formation of porous structures in said substrate by means of an etching process. The porous structures are for example tubes which are oriented parallel to one another and reach from an underside of the substrate as far as the semiconductor region serving as a stop layer. The remaining substrate between the tubes may optionally be removed by an etching process or remain for mechanical stabilization of the semiconductor power component. If the substrate situated between the tubes or the porous structures is removed, then the thinning process may be subdivided into two steps: In a first step, the tubes or the porous structures are etched, the depth of which is defined exactly to the target thickness by the semiconductor region serving as a stop layer. In a second step, the remaining substrate residue is then removed to the target thickness by introducing etchant to the porous structures or tubes. In any case, the depth of the part removed from the substrate by the etching processes is exactly defined by the position of the stop layer.

The formation of tubes or porous structures is not mandatory. The substrate may also be etched away all at once.

If the substrate residue remaining between the tubes or porous structures is removed, then the resulting underside of the semiconductor power component may have applied on it a highly doped semiconductor layer and, applied thereto, a layer made of highly conductive material, in order to form a corresponding contact. If the substrate situated between the porous structures is not removed, then it is possible, for the purpose of forming such a contact, firstly to produce a highly doped semiconductor layer or individual highly doped semiconductor regions by means of implantation/diffusion/deposition processes in the end region of the tubes that faces the semiconductor structure. The tube walls may then be covered with a highly conductive material, for example metal, by means of a deposition process, for example, thereby producing a contact between the highly doped semiconductor layer/the highly doped semiconductor regions at the end of the tubes and the underside of the substrate. Finally, a contact layer, for example made of metal, may be deposited on the rear side of the substrate, i.e., over the openings of the porous structures or tubes.

In order to enable a defined, parallel formation of the tubes, it is possible during the thinning process for a voltage to be applied to the semiconductor power component to be formed preferably between a top side of the semiconductor structure and an etching solution used for etching the substrate. The semiconductor power component is simultaneously illuminated. The electron-hole pairs produced by the illumination migrate on account of locally different field strengths to the ends of the tubes facing the semiconductor structure, where they react with the etchant which enables a defined formation of the tubes.

In order to produce a drift zone within the substrate, the substrate is usually subjected to a doping process as early as during fabrication (pulling process). What may be disadvantageous in this case, however, is that the doping concentration thereby achieved is subject to severe fluctuations. In order to avoid such doping fluctuations, according to the invention, the semiconductor structure comprising the drift zone is formed on the basis of implantation processes/diffusion processes in the substrate. It is thus possible to dispense with an epitaxy method for the deposition of the semiconductor structure on the substrate, which contributes to the reduction of the costs. Furthermore, it is possible also to form the semiconductor region serving as a stop layer by implantation processes/diffusion processes in the substrate or in the semiconductor structure (provided that this does not already exist per se through the semiconductor structure), and consequently on the one hand to avoid an epitaxy process and on the other hand to keep down fluctuations in the doping concentration.

One embodiment of the invention's method for fabricating a semiconductor transistor 10 is explained in more detail below.

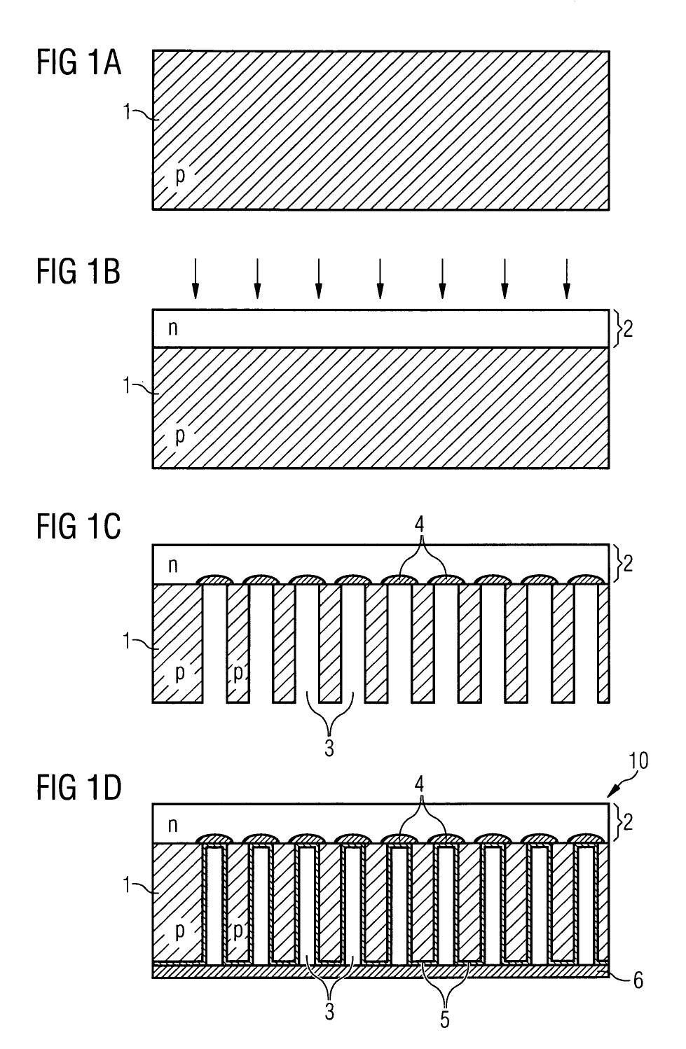

FIG. 1A illustrates a p-doped substrate 1. A semiconductor structure 2 is formed in the p-doped substrate 1 by means of an implantation process/diffusion process, said semiconductor structure initially merely comprising an n-doped layer. Further semiconductor regions/layers or metal/insulator layers may then be formed in/on the n-doped semiconductor layer likewise by means of implantation processes/diffusion processes and the like, so that a semiconductor component, for example a transistor, is finally formed in the semiconductor structure 2 (for clarity, the semiconductor/insulator/metal layers that are impressed/applied in/on the semiconductor structure 2 are not illustrated in FIG. 1B). The “residue” of the n-doped layer (that is to say that part of the n-doped layer which is situated below the impressed semiconductor/metal/insulator layers) forms the drift zone (likewise not explicitly illustrated in FIG. 1B). In this embodiment, the lower end of the semiconductor structure 2 simultaneously forms the semiconductor region serving as a stop layer, and a change in doping occurs at an interface between the substrate 1 and the semiconductor region serving as a stop layer (pn junction). The drift zone is situated above the semiconductor region serving as a stop layer, said drift zone likewise being a part of the semiconductor structure 2 and likewise being formed by means of implantation processes/diffusion processes in said substrate (the drift zone provided in the semiconductor structure 2 is not illustrated in FIG. 1B).

In FIG. 1C a local etching of the substrate 1 is carried out by means of a suitable etchant, thereby producing tubes 3 in the substrate 1, which extend from an underside of the substrate 1 as far as an underside of the semiconductor structure 2 (stop layer). In order to enable a precise formation of the tubes 3 it is optionally possible for a voltage to be applied between an etchant that etches the substrate 1 and a top side of the semiconductor structure 2 formed on the substrate 1 and for the semiconductor structure 2 to be illuminated. Since the effect of the etchant is doping-dependent, the formation of the tubes 3 is stopped at the semiconductor structure 2 (the etchant etches only p-doped material, but not n-doped material). A highly doped n-type layer, more precisely a plurality of highly doped n⁺-type “bumps” 4, is then produced by means of an implantation/diffusion process at the ends of the tubes 3 that face the semiconductor structure (see FIG. 1C). A continuous n⁺-type layer may also be produced instead of the n⁺-type “bumps” 4. In a final step, by means of a deposition process, for example, the inner walls of the tubes 3 are then covered with a highly conductive layer 5 and a contact layer 6, for example made of metal, is deposited on the underside of the substrate 1. The underside of the semiconductor structure 2 is accordingly contact-connected via the highly doped n-type layer 4, the highly conductive layer 5 and the contact layer 6.

In order to bring about an improved effect of stopping the etching of the tubes 3 at the semiconductor structure 2 (target thickness) it is possible, for example, to increase the doping concentration in the lower region of the semiconductor structure 2, that is to say to produce a semiconductor region serving as a stop layer with a high n-type concentration. It is thus possible to use a lightly doped n-type substrate and an efficient etching process.

In the development of new generations of DMOS power transistors one important aim is to reduce the on resistivity Ron·A. This makes it possible, on the one hand, to minimize the static power loss and, on the other hand, to achieve higher current densities. For modern low-voltage transistors, the Ron proportion of the chip Ron made up by the substrate is 20% to 30% despite very high substrate dopings. The starting material comprises highly doped substrate wafers on which the lightly doped drift path is deposited epitaxially. The epitaxy process leads to an increase in costs by more than a factor of two compared with a simple substrate wafer. It is an aim to eliminate the Ron substrate proportion and to save the epitaxy costs.

The Ron proportion can be reduced by thinning the wafer by grinding at the end of the process. In this case, thickness fluctuations in the starting wafer of typically 5 μm are transferred to the wafer that is thinned by grinding. Additional thickness fluctuations are generated by process fluctuations in the grinding process. It is thus not practical, in principle, for low-voltage components, to go over to epitaxy-free basic material wafers with doping at the drift path level (approximately 1·10¹⁵ . . . 1·10¹⁷ cm⁻³) because the Ron fluctuations on account of the thickness fluctuation are greater than the Ron proportion of the highly doped substrate. A further problem is posed by the high fluctuation in the dopant level above the bar during the pulling process, which is substantially higher (±25%) than the fluctuation in the epitaxy doping level (±6%).

In order to reduce the dopant fluctuation of the epitaxy-free basic material wafer, the present invention proceeds from a lightly n-doped to undoped or a lightly p-doped substrate material. The target doping of the drift path is then introduced by implantation and outdiffusion in the unthinned state from the front side. The doping fluctuation can thus be reduced to ±3%.

In order to reduce the thickness fluctuation after the thinning by grinding, according to embodiments of the invention an etching-back process is carried out which stops in a self-aligned manner at the end of the drift path formed by implantation and diffusion. For this purpose, the intention is to use an etching process which is dependent on the doping. What is ideal is a p-doped basic material (substrate) into which the n-type drift path is introduced from the top side by implantation and diffusion, in combination with an etching that etches only p-doped material and, consequently, automatically stops at the end of the drift zone. As an alternative, it is possible to use etchants that etch highly and lightly doped zones differently.

Consequently, according to the invention, the expensive highly doped basic material wafer with an epitaxial layer can be replaced by using an inexpensive lightly doped to undoped substrate and implantation and diffusion. The semiconductor power transistor according to the invention may be a planar/trench DMOS transistor, for example. KOH, for example, may be used for selective whole-area etching. It is also possible to use an n⁺-type substrate with n⁻-type epitaxy or n-type substrate with an n⁺-type stop layer below the drift zone.

The doped basic material is permeated with tubes from the rear side after the front-side processing in an electrolytic method. This may be affected in disordered fashion (nanoporous silicon) or in a predefined pattern (Lehmann tubes). The etching stops on the n-doped drift zone. The silicon permeated by tubes is etched away by means of an isotropic etching (wet-chemically or plasma etching). This etching need not be selective with respect to n-Si. Afterwards, a rear-side implantation and a metallization are preferably effected.

As an alternative, the p-type substrate permeated with tubes remains for the purpose of mechanical stabilization. The doping with a high concentration is effected by coating or from the gas phase or by implantation into the bottoms of the tubes. Finally, the tube walls are coated with a highly conductive material (metal, in particular tungsten, copper or silicide, Ti-nitride, . . . ), e.g., from the gas phase or electrochemically. Finally, a thick solderable or adhesive-bondable metal layer may be applied on the rear side.

A more reliable process implementation than in the exemplary embodiments described above can be achieved by the following method: An n⁻-doped basic material (substrate) is used; an n⁺-type zone is introduced at the lower end of the n⁻-type drift path, which zone acts as an etching stop layer and may later serve for the formation of the drain contact (preferably, use is made of a 1·10¹⁴ cm⁻² basic material with 1 μm 1·10¹⁹ cm⁻² covering layer. Hole sizes are in the range of 4 to 5 μm; 1 μm is also conceivable). The n⁺-type zone may be introduced by high-energy implantation, or be produced superficially and later be overgrown epitaxially (possibly not until after tube etching; the tubes should then be closed off or a high-temperature-resistant silicide or metal should be introduced). If the n⁺-type layer is buried, the n⁺-type layer of the wafer is electrically conduct—connected best at the edge during the etching process. Since the tube etching is effected through illumination-indicated holes, this is slowed down significantly in the n⁺-type zone, thereby homogenizing the etching depth across the entire wafer. At the same time, the current-voltage characteristic of the etching method changes, so that an endpoint signal is obtained.

If the intention is for p-type material to be etched away over the whole of the area (that is to say for no porous structures to be formed) and for n-type material to remain, then an etching solution comprising HF+HNO₃+glacial acetic acid (pure, anhydrous acetic acid) is appropriate, particularly if p⁺ is intended to be etched away. Furthermore, permanganate etching and chromium etching, which have the same effect, are also conceivable for p-type doping. The invention is not restricted to the etchants or doping ranges or hole sizes presented here.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method for fabricating a semiconductor power component, comprising:
forming a semiconductor structure in/on a substrate, including forming a semiconductor region serving as a stop layer being formed at the level of a target thickness of the semiconductor power component through the semiconductor structure/in the semiconductor structure or in the substrate, the doping concentration of said semiconductor region being increased/reduced with respect to that of the substrate, and/or the doping type of the semiconductor region being inverted with respect to that of the substrate; and
thinning of at least one part of the substrate to the target thickness using an etchant whose etching rate is dependent on the concentration and/or the type of the doping, the etchant being chosen such that the thinning process is stopped or slowed down by the semiconductor region serving as a stop layer.

2. The method of claim 1, wherein the thinning process of the substrate comprises forming porous structures in the substrate using an etching process.

3. The method of claim 2, wherein the porous structures are tubes reaching from the underside of the substrate as far as the semiconductor region serving as a stop layer.

4. The method of claim 3, comprising removing the substrate between the tubes by an etching process.

5. The method of claim 3, comprising producing a highly doped semiconductor layer by implantation processes/diffusion processes/deposition processes in the end region of the tubes that faces the semiconductor structure.

6. The method of claim 5, comprising covering the tube walls with a conductive material.

7. The method of claim 6, comprising depositing a metal layer on the rear side of the substrate over the openings of the tubes.

8. The method of claim 2, wherein the thinning process further comprises applying a voltage to the semiconductor power component to be formed and the semiconductor power component is illuminated.

9. The method of claim 1, wherein the thinning process of the substrate is affected by whole-area etching of the substrate.

10. The method of claim 1, comprising:
controlling doping of the semiconductor structure by implantation processes/diffusion processes.

11. The method of claim 1, comprising:
forming the semiconductor region serving as a stop layer by implantation processes/diffusion processes in the substrate or in the semiconductor structure.

12. A method for fabricating a semiconductor power component, having the following steps:
formation of a semiconductor structure in a substrate, a semiconductor region serving as a stop layer being formed at the level of a target thickness of the semiconductor power component through the semiconductor structure, the doping concentration of said semiconductor region being altered with respect to that of the substrate, or the doping type of said semiconductor region being inverted with respect to that of the substrate;
thinning of at least one part of the substrate to the target thickness using an etchant whose etching rate is dependent on the concentration or the type of the doping, the etchant being chosen such that the thinning process is stopped or slowed down by the semiconductor region serving as a stop layer.

13. The method of claim 12, wherein the thinning process of the substrate comprises forming porous structures in the substrate using an etching process.

14. The method of claim 13, wherein the porous structures are tubes reaching from the underside of the substrate as far as the semiconductor region serving as a stop layer.

15. The method of claim 14, comprising removing the substrate between the tubes by an etching process.

16. The method of claim 14, comprising producing a highly doped semiconductor layer by implantation processes/diffusion processes/deposition processes in the end region of the tubes that faces the semiconductor structure.

17. The method of claim 16, comprising covering the tube walls with a conductive material.

18. The method of claim 17, comprising depositing a metal layer on the rear side of the substrate over the openings of the tubes.

19. The method of claim 13, wherein the thinning process further comprises applying a voltage to the semiconductor power component to be formed and the semiconductor power component is illuminated.

20. The method of claim 12, wherein the thinning process of the substrate is affected by whole-area etching of the substrate.

21. A method for fabricating a semiconductor power component, comprising:
forming a semiconductor structure in/on a substrate, including forming a semiconductor region serving as a stop layer being formed at the level of a target thickness of the semiconductor power component through the semiconductor structure/in the semiconductor structure or in the substrate, the doping concentration of said semiconductor region being increased/reduced with respect to that of the substrate, and/or the doping type of the semiconductor region being inverted with respect to that of the substrate;
thinning of at least one part of the substrate to the target thickness using an etchant whose etching rate is dependent on the concentration and/or the type of the doping, the etchant being chosen such that the thinning process is stopped or slowed down by the semiconductor region serving as a stop layer;
controlling doping of the semiconductor structure by implantation processes/diffusion processes; and
forming the semiconductor region serving as a stop layer by implantation processes/diffusion processes in the substrate or in the semiconductor structure.

22. The method of claim 21, wherein the thinning process of the substrate comprises forming porous structures in the substrate using an etching process, wherein the porous structures are tubes reaching from the underside of the substrate as far as the semiconductor region serving as a stop layer, further comprising:
removing the substrate between the tubes by an etching process; and
producing a highly doped semiconductor layer by implantation processes/diffusion processes/deposition processes in the end region of the tubes that faces the semiconductor structure.

23. The method of claim 22, further comprising:
covering the tube walls with a conductive material;
depositing a metal layer on the rear side of the substrate over the openings of the tubes; and
wherein the thinning process further comprises applying a voltage to the semiconductor power component to be formed and the semiconductor power component is illuminated.
